(19) United States
(12) Patent Application Publication
(10) Pub. No.: US 2006/0265870 A1
(43) Pub. Date: Nov. 30, 2006

(54) Printed circuit board and printed circuit board manufacturing method

(75) Inventors: Kiyozumi Gotou, Echizen-shi (JP); Naoto Nakamura, Echizen-shi (JP)

Correspondence Address: REED SMITH LLP, Suite 1400, 3110 Fairview Park Drive, Falls Church, VA, 22042, US

(73) Assignee: Orion Electric Company Ltd.

(21) Appl. No.: 11/442,115

(22) Filed: May 30, 2006

(30) Foreign Application Priority Data
May 31, 2005 (JP) 2005-160279

(51) Int. Cl. H05K 3/20; H05K 1/16

(52) U.S. Cl. 29/831; 29/846; 29/852; 174/260

(57) ABSTRACT

An alignment mark for aligning a resist film and a silk film relative to a printed circuit board is used as a reference mark based on which a position of an electronic component on the printed circuit board is acquired when a component mounting machine mounts the electronic component on the printed circuit board. This makes it unnecessary to additionally provide a board recognition mark and an individual recognition mark, thereby making it possible to effectively use an area of the printed circuit board. In addition, since the number of marks to be recognized is decreased, a recognition processing is reduced. Accordingly, mounting time and a mounting program can be reduced, and a manufacturing cost of the printed circuit board can be reduced.

### BACKGROUND OF THE INVENTION

1. Field of the Invention

The present invention relates to a printed circuit board used in an electric or electronic apparatus and a method for manufacturing the printed circuit board.

2. Description of the Related Art

FIG. 5 shows an example of a conventional printed circuit board used in an electronic apparatus. On a printed circuit board 50, alignment marks 52 based on which a resist film and a silk film are aligned during a resist coating operation and a silk coating operation, and board recognition marks 53 and individual recognition marks 54 based on which position information on each electronic component 5 on the printed circuit board 50 is acquired when the electronic component 5 is mounted on the printed circuit board 50 by a component mounting machine are provided. Procedures for manufacturing this printed circuit board 50 will next be described with reference to FIGS. 5 to 9A to 9E.

FIGS. 6A to 6E show procedures for forming a copper foil pattern (wiring pattern) (particularly an alignment mark 52 part) on an insulating substrate 11. FIGS. 6A to 6D are cross-sectional views of the printed circuit board 50, and FIG. 6E is a top view of the alignment mark 52. As shown in FIG. 6A, a pattern film 18, on which a required copper foil pattern is printed, is applied relative to the printed circuit board 50 having a copper foil 12 bonded onto the insulating substrate 11, and an etching resist 19 is coated onto an upper surface of the board 50. As a result, as shown in FIG. 6B, the etching resist 19 remains according to a shape of the required copper foil pattern. As shown in FIG. 6C, an etching treatment is carried out to etch away unnecessary parts of the copper foil 12. Finally, as shown in FIG. 6D, when the remaining etching resist 19 is removed, the required copper foil pattern can be formed on the insulating substrate 11. Through these copper foil pattern forming procedures, the alignment mark 52 can be formed. FIG. 6E shows the alignment mark 52 formed in a central portion of FIG. 6D.

FIGS. 7A to 7C show resist coating procedures. FIGS. 7A and 7B are cross-sectional views of the printed circuit board 50, and FIG. 7C is a top view of the alignment mark 52. A resist film 15 is aligned based on edges of the copper foil 12 (denoted by symbol E in FIG. 6E) at the center of the alignment mark 52 shown in FIG. 7C and a resist 13 is coated onto the upper surface of the board 50. As a result, as shown in FIG. 7B, the resist 13 is coated according to a shape of the resist film 15. FIG. 7C shows the alignment mark 52 at this moment.

FIGS. 8A to 8C show silk coating procedures. FIGS. 8A and 8B are cross-sectional views of the printed circuit board 50, and FIG. 8C is a top view of the alignment mark 52. A silk film 17 is aligned based on positions denoted by symbol F in FIG. 8A and a silk 14 is coated onto the upper surface of the board 50. As a result, as shown in FIG. 8B, the silk 14 is coated according to a shape of the silk film 17. FIG. 8C shows the alignment mark 52 at this moment.

After the silk 14 is coated, components 5 are mounted on the printed circuit board 50. During this time, the component mounting machine recognizes the board recognition marks 53 as an image and acquires position information on each of the components 5 on the printed circuit board 50. Based on the position information on each component 5 on the printed circuit board 50 thus acquired as well as component mounting information (e.g., an order of mounting the components 5, types of the components 5, and relative coordinates of mounting positions of the components 5) stored in advance, the component mounting machine mounts the components 5 on the printed circuit board 50. If it is necessary to improve accuracy for the mounting positions of the components 5, the individual recognition marks 54 (see FIG. 5) are provided in the vicinity of mounting locations of the respective components 5. The component mounting machine further recognizes the marks 54 as an image. The board recognition marks 53 and the individual recognition marks 54 will be generically referred to as “recognition marks” hereinafter in the specification of the present invention. FIGS. 9A to 9E show procedures for forming the recognition marks. FIGS. 9A to 9D are cross-sectional views of the printed circuit board 50 (particularly a recognition mark part), and FIG. 9E is a top view of the recognition mark. The recognition marks can be formed simultaneously with formation of the copper foil pattern shown in FIG. 6. It is noted that the recognition marks specify locations of high reflectance (or low reflectance) parts by forming parts different in optical reflectance.

Meanwhile, in recent years, several respects are required of the printed circuit board. For instance, following a reduction in a size of an apparatus, a smaller-sized printed circuit board is used, and an improvement in utilization efficiency of the printed circuit board is demanded accordingly. In addition, a reduction in assembly time is demanded for purposes of, for example, advancing an appointment date of delivery and reducing cost.

Japanese Utility Model Application Laid-Open No. 06-013139 discloses a technique for reducing a magnitude of a recognition mark itself. Japanese Patent Application Laid-Open No. 2003-283074 discloses a technique for space saving by providing individual recognition marks in mounting spaces of components to be mounted later.

The techniques disclosed in both Japanese Utility Model Application Laid-Open No. 06-013139 and Japanese Patent Application Laid-Open No. 2003-283074 can make effective use of the printed circuit board. However, since the number of marks does not change, the effect of the effective use of the board is small. In addition, the reduction in the assembly time cannot be expected from the techniques disclosed therein.

### SUMMARY OF THE INVENTION

The present invention has been achieved to solve the conventional disadvantages. It is an object of the present invention to make effective use of an area of a printed circuit board by decreasing the number of marks on the board, to reduce component mounting time to follow the reduction in the number of times of recognition, and to simplify a mounting program.

According to a first aspect of the present invention, there is provided a printed circuit board comprising, on an insulating substrate, a conductive film layer for forming a wiring pattern; a resist layer for preventing a solder from adhering to unintended regions of the conductive film layer for forming the wiring pattern; and an information printing layer for printing and displaying various pieces of information; wherein a mark central portion is formed on the conductive film layer by a conductive film missing portion after having removed a conductive film around the mark central portion, a resist missing portion is arranged on the resist layer concentrically with the mark central portion, the resist missing portion having an external shape similar to a shape of the mark central portion and exposing at least a part of the conductive film missing portion and the mark central portion, and an information printing layer alignment mark is arranged on the information printing layer concentrically with the mark central portion, the information printing layer alignment mark having a figure similar to the shape of the mark central portion, the figure indicated by a boundary line representing an external shape of the information printing layer alignment mark, and exposing at least a part of the conductive film missing portion and the mark central portion, hereby forming an alignment mark on the printed circuit board.

According to the first aspect of the present invention, the printed circuit board has none of the conductive film layer, the resist layer, and the information printing layer (e.g., silk screen printing layer) formed in a certain region around the mark central portion consisting of the conductive film (e.g., copper foil film) that is a material having an optically high reflectance.

According to a second aspect of the present invention, there is provided the printed circuit board according to the first aspect, wherein the information printing layer alignment mark is formed so that the boundary line that indicates the external shape of the information printing layer alignment mark is not overlapped with a boundary line of a region in which the resist missing portion is formed.

According to the second aspect of the present invention, the printed circuit board has the boundary line of the mark central portion, the boundary line of the region in which the resist missing portion is formed, and the boundary line that indicates the external shape of the information printing layer alignment mark arranged concentrically so as not to be overlapped with one another.

According to a third aspect of the present invention, there is provided the printed circuit board according to the first or second aspect, wherein a distance between the mark central portion and each of the conductive film, the resist, and the information printing layer alignment mark is 0.7 millimeters or more.

According to the third aspect of the present invention, the printed circuit board has a portion, the width of which is 0.7 millimeters or more and in which the insulating substrate is exposed, formed around the mark central portion (which portion means a portion in which the conductive film layer, the resist layer, and the information printing layer are not present, and which portion is not necessarily limited to a portion in which the insulating substrate is exposed in a state in which the printed circuit board is completed).

According to a fourth aspect of the present invention, there is provided a method for manufacturing a printed circuit board, the printed circuit board including, on an insulating substrate, a conductive film layer for forming a wiring pattern; a resist layer for preventing a solder from adhering to unintended regions of the conductive film layer for forming the wiring pattern; and an information printing layer for printing and displaying various pieces of information; wherein a mark central portion is formed on the conductive film layer by a conductive film missing portion after having removed a conductive film around the mark central portion, a resist missing portion is arranged on the resist layer concentrically with the mark central portion, the resist missing portion having an external shape similar to a shape of the mark central portion and exposing at least a part of the conductive film missing portion and the mark central portion, and an information printing layer alignment mark is arranged on the information printing layer concentrically with the mark central portion, the information printing layer alignment mark having a figure similar to the shape of the mark central portion, the figure indicated by a boundary line representing an external shape of the information printing layer alignment mark, and exposing at least a part of the conductive film missing portion and the mark central portion, hereby forming an alignment mark on the printed circuit board, the method comprising steps of: forming the mark central portion on the conductive film layer; aligning a resist film relative to the printed circuit board based on the mark central portion or the conductive film missing portion and coating a resist; aligning a silk film relative to the printed circuit board based on the resist missing portion formed by coating the resist, the mark central portion, or the conductive film missing portion and coating a silk; and causing a component mounting machine to acquire position information on an electronic component on the printed circuit board by the alignment mark when the component mounting machine mounts the electronic component on the printed circuit board.

According to the fourth aspect of the present invention, with the method for manufacturing the printed circuit board, the position information on the electronic component on the printed circuit board is acquired by the alignment mark when the component mounting machine mounts the electronic component on the printed circuit board.

According to the first aspect of the present invention, the printed circuit board is configured so that none of the conductive film layer, the resist layer, and the information printing layer (e.g., silk screen printing layer) are formed (i.e., the insulating substrate is exposed) in the certain region around the mark central portion consisting of the conductive film (e.g., copper foil film) which is a material having an optically high reflectance. Due to this, the alignment mark can be used as “recognition mark” (since an insulating substrate portion lower in optical reflectance than the mark central portion is formed around the mark central portion). Thus, “recognition marks” can be reduced. Therefore, the number of marks on the printed circuit board can be decreased, and the area of the board can be effectively used.

According to the second aspect of the present invention, the printed circuit board is configured so that the boundary line of the mark central portion, the boundary line of the region in which the resist missing portion is formed, and the boundary line that indicates the external shape of the information printing layer alignment mark are arranged concentrically so as not to be overlapped with one another (i.e., figures formed by the respective layers are arranged to be concentric and superimposed). Therefore, it is possible to facilitate visually recognizing whether the respective layers are shifted relative to one another by the alignment mark.

According to the third aspect of the present invention, the printed circuit board is configured so that the portion the width of which is 0.7 millimeters or more and in which the insulating substrate is exposed (the portion having a lower optical reflectance) is formed around the mark central portion (the portion having a higher optical reflectance). Due to this, it is possible to improve accuracy for recognition of the mark central portion by the component mounting machine (i.e., accuracy for the acquired position information on the component on the printed circuit board).

### BRIEF DESCRIPTION OF THE DRAWINGS

FIG. 1 is a schematic top view of a printed circuit board according to an embodiment of the present invention;

FIGS. 2A to 2C are explanatory views of a resist coating step for the printed circuit board according to the embodiment;

FIGS. 3A to 3C are explanatory views of a silk coating step for the printed circuit board according to the embodiment;

FIGS. 4 to 4D are explanatory views of a resist coating step and a silk coating step for a printed circuit board according to another embodiment;

FIG. 5 is a schematic top view of a conventional printed circuit board;

FIGS. 6A to 6E are explanatory views of an etching step for the conventional printed circuit board;

FIGS. 7A to 7C are explanatory views of a resist coating step for the conventional printed circuit board;

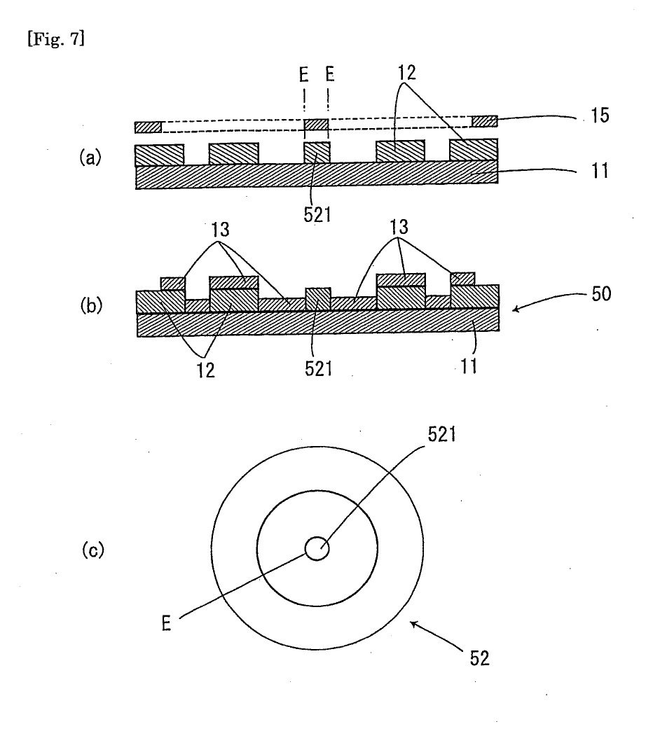

FIGS. 8A to 8C are explanatory views of a silk coating step for the conventional printed circuit board; and

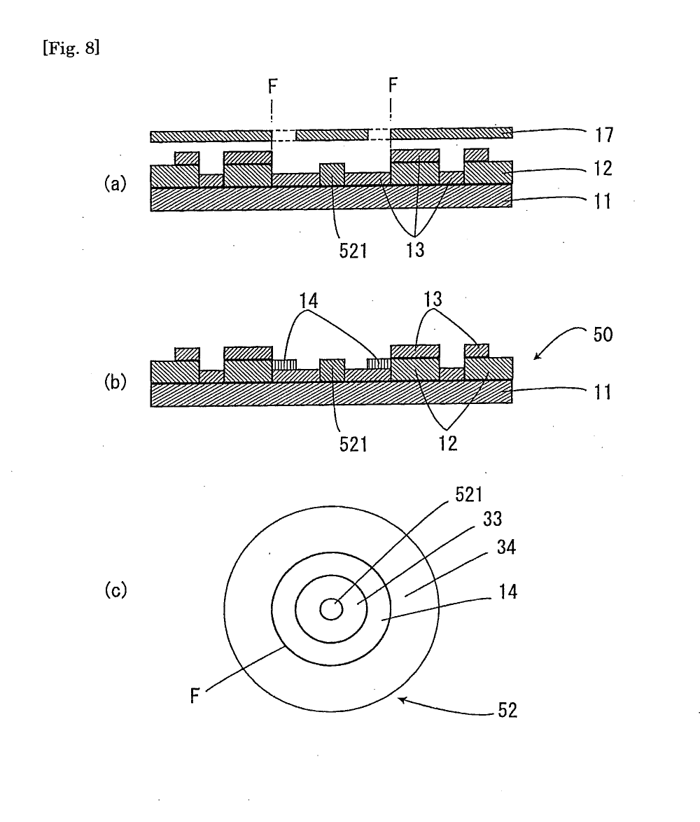

FIGS. 9A to 9E are explanatory views of a recognition mark forming step for the conventional printed circuit board.

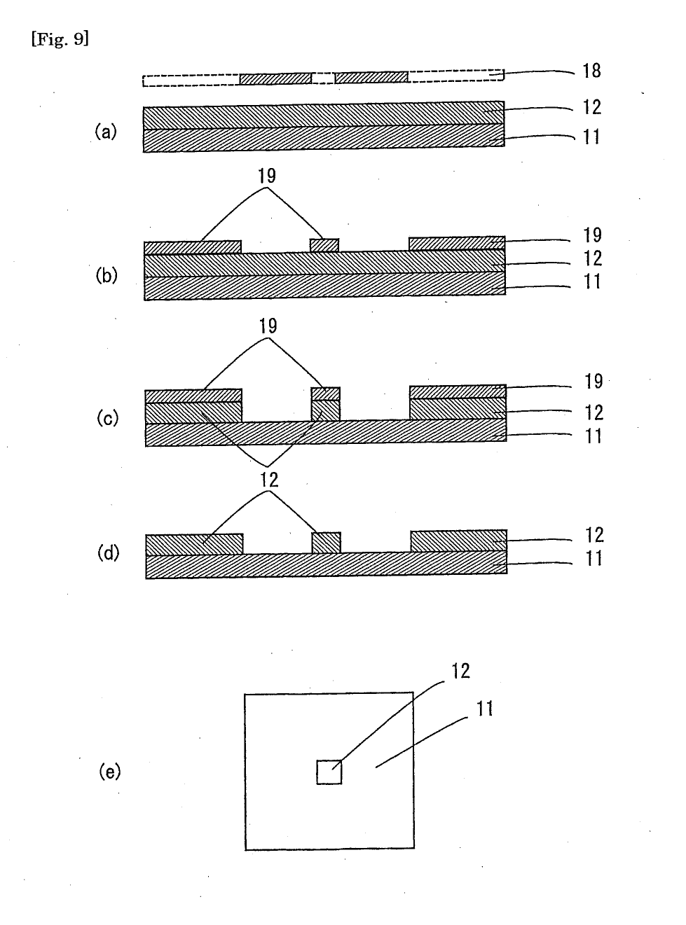

### DESCRIPTION OF THE PREFERRED EMBODIMENT

A preferred embodiment of the present invention will be described hereinafter with reference to the drawings. It is noted, however, that the embodiment is merely one specific example of the present invention and that the present invention is not limited to the embodiment.

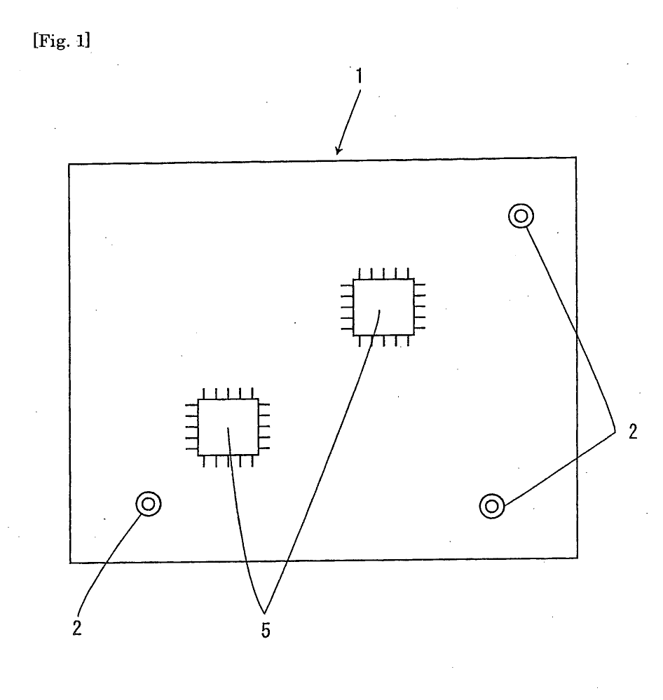

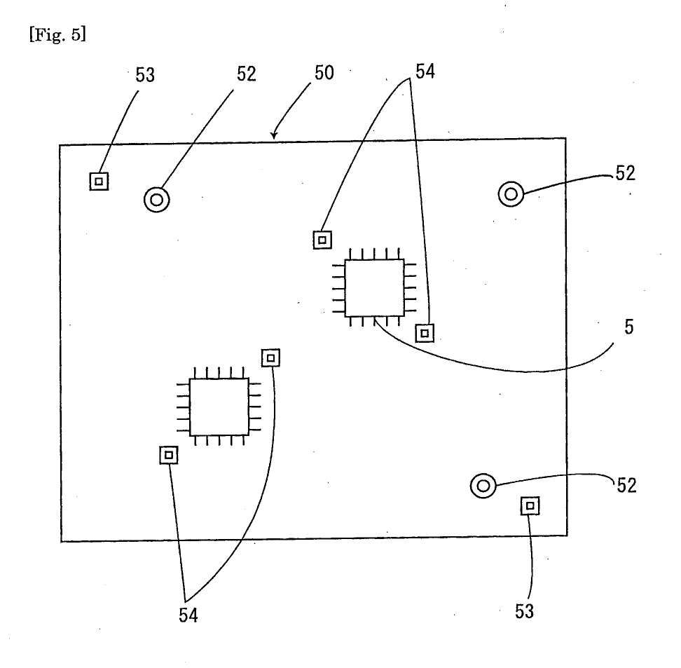

FIG. 1 is a top view of a printed circuit board 1 according to an embodiment of the present invention. On the printed circuit board 1, as shown in FIG. 1, an alignment mark 2 is formed, and electronic components 5, which are surface mount components, are mounted. Although not shown in FIG. 1, a wide variety of electronic components are actually mounted on the printed circuit board 1, and letters or the like indicating information on the respective components 5 are printed thereon by silk screen printing. On the conventional printed circuit board 50, the recognition marks (the board recognition marks 53 and the individual recognition marks 54) are provided separately from the alignment marks 52 as shown in FIG. 5. According to this embodiment, by contrast, no recognition marks (marks used only as recognition marks) are formed on the printed circuit board 1 (shown in FIG. 1).

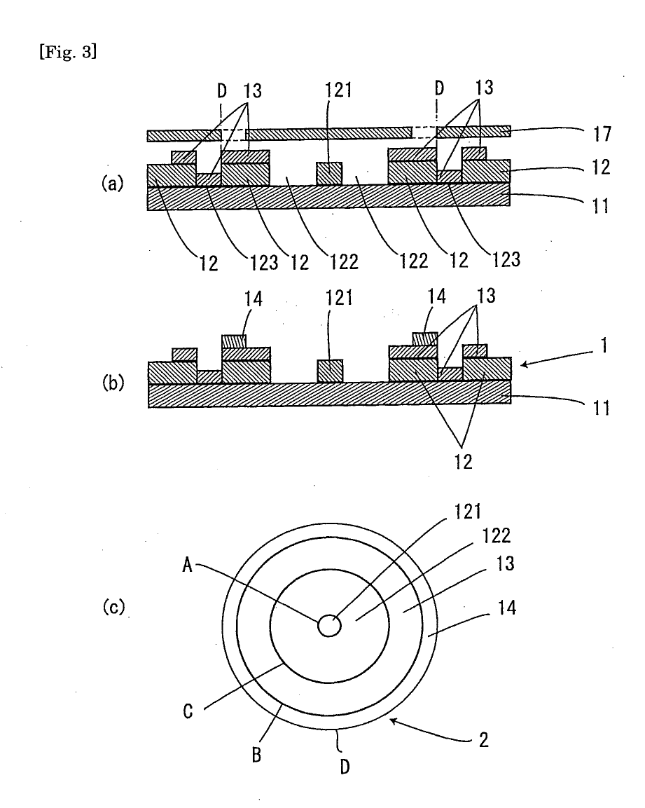

FIG. 3B is a schematic cross-sectional view of the printed circuit board 1 (particularly an alignment mark 2 part) according to this embodiment. The printed circuit board 1 includes a copper foil (conductive film layer) 12 for forming a wiring pattern, a resist 13 (resist layer) for preventing a solder from adhering to unintended regions of the copper foil 12 for forming the wiring pattern, and a silk screen printing layer (an information printing layer) 14 for printing and displaying various pieces of information (e.g., information on the electronic components 5 mounted on the printed circuit board 1), which are provided on an insulating substrate 11.

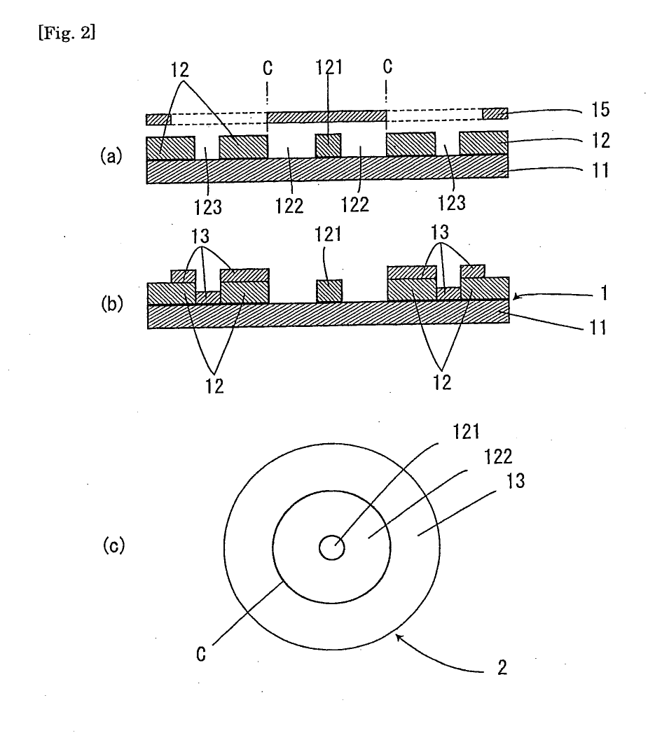

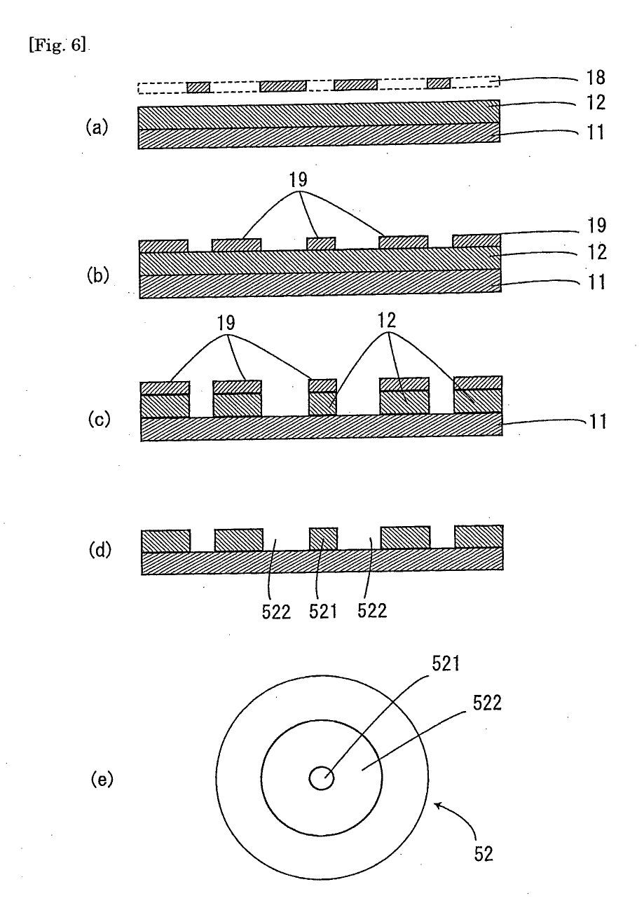

Procedures for manufacturing the printed circuit board 1 according to this embodiment will be described. First of all, similarly to the conventional printed circuit board 50 (see FIGS. 6A to 6E), a wiring pattern is formed. In steps of forming the wiring pattern, a mark central portion 121 is formed circularly by a copper foil missing portion 122 (indicated in FIG. 2A) from which the copper foil 12 around the mark central portion 121 has been removed (i.e., the mark central portion 121 is formed by forming the copper foil missing portion 122 by an etching).

FIGS. 2A to 2C show resist coating procedures. FIGS. 2A and 2B are schematic cross-sectional views of the printed circuit board 1 (particularly the alignment mark 2 part) and FIG. 2C is a top view of the alignment mark 2. A resist film 15 is aligned relative to the printed circuit board 1 based on the copper foil missing portion 122 (indicated by C in FIG. 2A) and a resist 13 is coated on an upper surface of the printed circuit board 1. As a result, as shown in FIG. 2B, the resist 13 is coated according to a shape of the resist film 15 (so that the copper foil missing portion 122 and the mark central portion 121 are exposed in a circular shape similar to the shape of the mark central portion 121 and the resist 13 is coated concentrically) FIG. 2C shows the alignment mark 2 at this moment. An internal part of C shown in FIG. 2C serves as the resist missing portion in which the resist 13 is not coated (an external shape of the resist missing portion (a figure formed by C shown in FIG. 2C) is similar to the shape of the mark central portion 121).

FIGS. 3A to 3C show silk coating procedures. FIGS. 3A and 3B are schematic cross-sectional views of the printed circuit board 1, and FIG. 3C is a top view of the alignment mark 2. A silk film 17 is aligned relative to the printed circuit board 1 based on the copper foil missing portion 123 (denoted by D in FIG. 3A) and a silk 14 is coated onto the upper surface of the printed circuit board 1. As a result, as shown in FIG. 3B, the silk 14 is coated according to the shape of the silk film 17 (the silk 14 is coated in a doughnut-like shape similar to the shape of the mark central portion 121 so that the silk 14 is not superimposed on the copper foil missing portion 122 and the mark central portion 121). A silk alignment mark (an information printing layer alignment mark) is thereby formed. FIG. 3C shows the alignment mark 2 at this moment (a figure formed by a boundary line (denoted by B in FIG. 3C) that indicates an external shape of the silk alignment mark is similar in shape to the mark central portion 121). A width of a region (copper foil missing portion 122) in which the insulating substrate 11 is visible is 0.7 millimeters or more. Thus, the copper foil layer, the resist layer, and the silk screen printing layer are formed on the insulating substrate 11, and the alignment mark 2 is formed.

In steps of mounting the electronic components 5 on the printed circuit board 1 on which the alignment marks 2 are thus formed using the component mounting machine (not shown), the machine recognizes the alignment marks 2 as shown in FIG. 3C as an image, and acquires position information on each of the components 5 on the printed circuit board 1. In addition, the component mounting machine mounts the electronic components 5 based on the position information thereon on the printed circuit board 1 as well as mounting information on the electronic components 5 on the printed circuit board 1 stored in advance (such as an order of mounting the electronic components 5, types of the electronic components 5, and relative coordinates of the mounting positions of the electronic components 5). During this time, the component mounting machine recognizes the marks 2 as the image using a difference in optical reflectance between the region (copper foil missing portion 122) in which the insulating substrate 11 is exposed shown in FIG. 3C and the region (mark central portion 121) in which the copper foil 12 is exposed.

As stated so far, according to the present invention, the components 5 can be mounted on the printed circuit board 1 using the alignment marks 2 without providing new recognition marks. Namely, the number of marks on the printed circuit board 1 can be decreased, and the area of the board 1 can be effectively used. Further, the boundary line (denoted by A in FIG. 3C) of the mark central portion 121, the boundary line (denoted by C in FIG. 3C) of the region in which the resist missing portion is formed, and the boundary line (denoted by B in FIG. 3C) that indicates the external shape of the silk alignment mark on the alignment mark 2 are arranged concentrically so as not to be overlapped with one another. Therefore, it is possible to facilitate visually recognizing whether the respective layers are shifted relative to one another by the alignment marks 2. Further, the portion (copper foil missing portion 122) the width of which is 0.7 millimeters or more and in which the insulating substrate 11 is exposed is formed around the mark central portion 121. Due to this, it is possible to improve accuracy for recognition of the mark central portion 121 by the component mounting machine (i.e., accuracy for the acquired position information on each component 5 on the printed circuit board) Besides, according to this embodiment, since the individual recognition marks 54 formed on the conventional printed circuit board 50 (FIG. 5) are not provided thereon, the number of times of position recognition by the component mounting machine is decreased, component mounting time can be reduced, and the number of steps for a recognition-related processing by a mounting program can be decreased. Therefore, cost can be reduced (it is noted that the accuracy for the mounting position of each electronic component 5 is maintained by providing the alignment mark 2 at a location generally on an extension of a diagonal of the electronic component 5 on the printed circuit board 1 according to the embodiment).

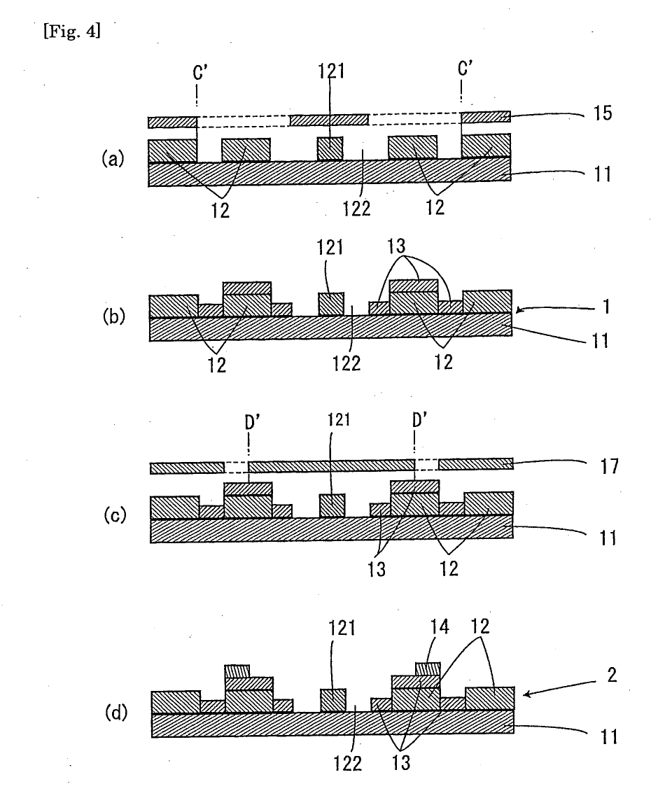

In the above-stated embodiment, the mark 2 is circular in shape. However, the present invention is not limited to this. The shape of the mark 2 may be other than the circular shape such as a polygonal shape or an elliptical shape. In the above-stated embodiment, as the boundary line that indicates the external shape of the silk alignment mark, the internal doughnut-shaped boundary line is used. However, the present invention is not limited to this. An external boundary line may be used. In addition, the configuration of the alignment mark according to the present invention is not limited to those shown in FIGS. 2A to 2C and 3A to 3C and can be variously changed within the scope of the concept stated above. For instance, as shown in FIGS. 4A to 4D (in which like constituent elements as those shown in FIGS. 2A to 2C and 3A to 3C are denoted by the same reference symbols, respectively), the resist 13 (or the silk 14) may be overlapped with a part of the copper foil missing portion 122 (in this case, similarly to the above-stated embodiment, it is preferable to secure that the width of the region in which the insulating substrate 11 is exposed is 0.7 millimeters or more so as to ensure the accuracy for the recognition of the mark central portion 121 by the component mounting machine).

1. A printed circuit board comprising, on an insulating substrate:
a conductive film layer for forming a wiring pattern;
a resist layer for preventing a solder from adhering to unintended regions of the conductive film layer for forming the wiring pattern; and
an information printing layer for printing and displaying various pieces of information, wherein
a mark central portion is formed on the conductive film layer by a conductive film missing portion after having removed a conductive film around the mark central portion, a resist missing portion is arranged on the resist layer concentrically with the mark central portion, the resist missing portion having an external shape similar to a shape of the mark central portion and exposing at least a part of the conductive film missing portion and the mark central portion, and an information printing layer alignment mark is arranged on the information printing layer concentrically with the mark central portion, the information printing layer alignment mark having a figure similar to the shape of the mark central portion, the figure indicated by a boundary line representing an external shape of the information printing layer alignment mark, and exposing at least a part of the conductive film missing portion and the mark central portion, hereby forming an alignment mark on the printed circuit board.

2. The printed circuit board according to claim 1, wherein the information printing layer alignment mark is formed so that the boundary line that indicates the external shape of the information printing layer alignment mark is not overlapped with a boundary line of a region in which the resist missing portion is formed.

3. The printed circuit board according to claim 1, wherein
a distance between the mark central portion and each of the conductive film, the resist, and the information printing layer alignment mark is 0.7 millimeters or more.

4. A method for manufacturing a printed circuit board, the printed circuit board including, on an insulating substrate, a conductive film layer for forming a wiring pattern; a resist layer for preventing a solder from adhering to unintended regions of the conductive film layer for forming the wiring pattern; and an information printing layer for printing and displaying various pieces of information; wherein a mark central portion is formed on the conductive film layer by a conductive film missing portion after having removed a conductive film around the mark central portion, a resist missing portion is arranged on the resist layer concentrically with the mark central portion, the resist missing portion having an external shape similar to a shape of the mark central portion and exposing at least a part of the conductive film missing portion and the mark central portion, and an information printing layer alignment mark is arranged on the information printing layer concentrically with the mark central portion, the information printing layer alignment mark having a figure similar to the shape of the mark central portion, the figure indicated by a boundary line representing an external shape of the information printing layer alignment mark, and exposing at least a part of the conductive film missing portion and the mark central portion, hereby forming an alignment mark on the printed circuit board, the method comprising steps of:
forming the mark central portion on the conductive film layer;
aligning a resist film relative to the printed circuit board based on the mark central portion or the conductive film missing portion and coating a resist;
aligning a silk film relative to the printed circuit board based on the resist missing portion formed by coating the resist, the mark central portion, or the conductive film missing portion and coating a silk; and
causing a component mounting machine to acquire position information on an electronic component on the printed circuit board by the alignment mark when the component mounting machine mounts the electronic component on the printed circuit board.

5. The printed circuit board according to claim 2, wherein
a distance between the mark central portion and each of the conductive film, the resist, and the information printing layer alignment mark is 0.7 millimeters or more.
